(19) United States
(12) Patent Application Publication
(10) Pub. No.: US 2012/0293945 A1
(43) Pub. Date: Nov. 22, 2012

(54) FIXING APPARATUS FOR HARD DISK DRIVE

(75) Inventors: ZHI-CHENG WANG, Shenzhen City (CN); GUANG-YAO LEE, Tu-Cheng (TW); CHIEN-LI TSAI, Tu-Cheng (TW); JIE ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/207,458

(22) Filed: Aug. 11, 2011

(30) Foreign Application Priority Data
May 20, 2011 (CN) 201110131430.3

(51) Int. Cl. H05K 7/00

(52) U.S. Cl. 361/679.33

(57) ABSTRACT

A fixing apparatus for fixing a hard disk drive including two opposite sidewalls each defining a fixing hole includes a frame, two shock absorbing members, and two fasteners. The frame includes two opposite fixing arms to sandwich the hard disk drive. The shock absorbing members are respectively fixed to the fixing arms. Each of the shock absorbing members includes a resilient pad clinging to an inner surface of a corresponding one of the fixing arms to absorb shock between the hard disk drive and the fixing arm, and two resilient arms extended through the corresponding fixing arm and fixed to an outer surface of the corresponding fixing arm. The fasteners are respectively fixed to the fixing arms. Each of the fasteners includes a pin extended through a corresponding one of the resilient pads, to engage in a corresponding one of the fixing holes of the hard disk drive.

### BACKGROUND

1. Technical Field

The present disclosure relates to an apparatus for fixing a hard disk drive.

2. Description of Related Art

An electronic device, such as a computer, generally includes a frame, and a plurality of screws extending through the frame to fix a hard disk drive and connect the hard disk drive to ground. However, these screws are usually small and difficult to handle, the installation of the hard disk drive in the computer is labor-intensive. Additionally, the hard disk drive installed in the frame may be too easily damaged by vibrations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an exemplary embodiment of a fixing apparatus, wherein the fixing apparatus includes a plurality of shock absorbing members.

FIG. 2 is an assembled, isometric view of the fixing apparatus of FIG. 1, together with a hard disk drive.

FIG. 3 is an enlarged view of one of the shock absorbing members of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

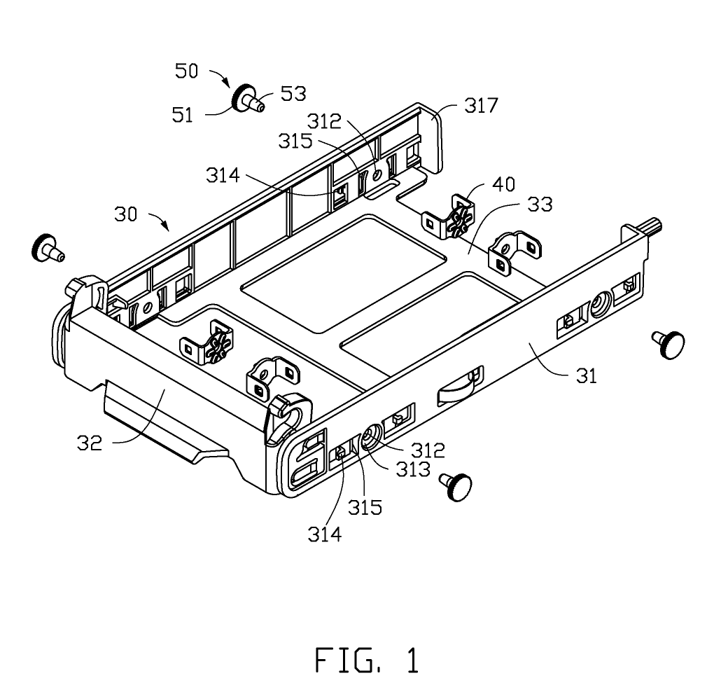

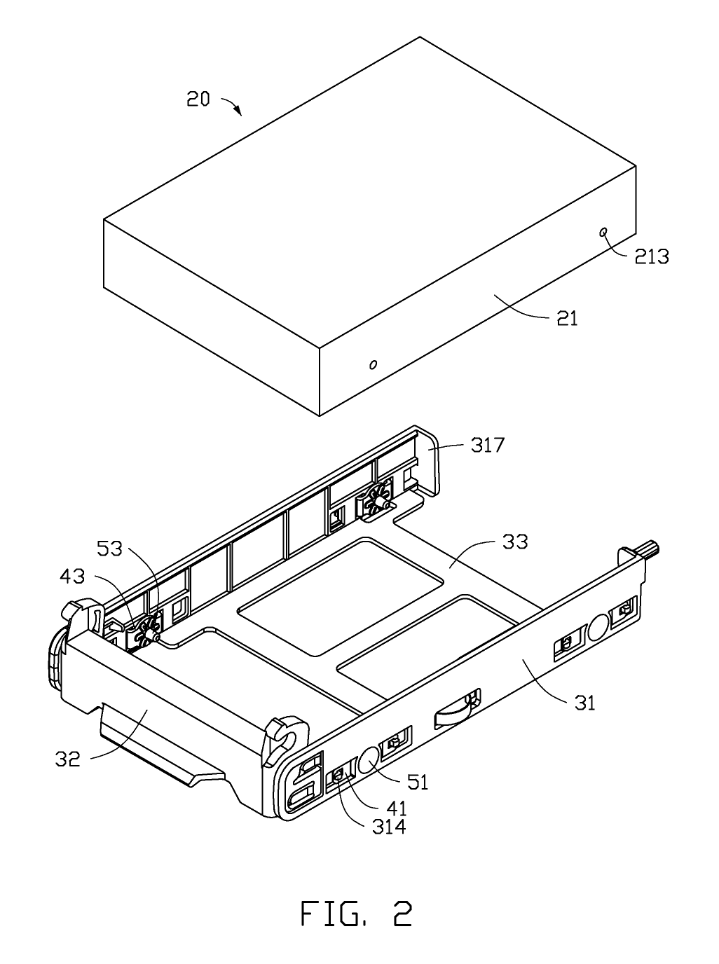

Referring to FIGS. 1 and 2, an embodiment of a fixing apparatus is provided to fix a hard disk drive 20. The hard disk drive 20 includes two opposite sidewalls 21. Two spaced fixing holes 213 are defined in each sidewall 21. The fixing apparatus includes a frame 30, four resilient shock absorbing members 40, and four fasteners 50.

The frame 30 includes two resilient fixing arms 31, a connecting arm 32 connected between first ends of the fixing arms 31, and a bottom wall 33 connected between bottoms of the fixing arms 31. Two through holes 312 are defined in each fixing arm 31. Two circular recesses 313 are defined in an outer surface of each fixing arm 31, in communication with the corresponding through holes 312 of the fixing arm 31. The outer surface of each fixing arm 31 forms two hooks 314 extending away from each other from opposite sides of each recess 313. A through slot 315 is defined in the fixing arm 31 between each hook 314 and the adjacent recess 313. Two stop plates 317 extend toward each other from second ends of the fixing arms 31 away from the connecting arm 32.

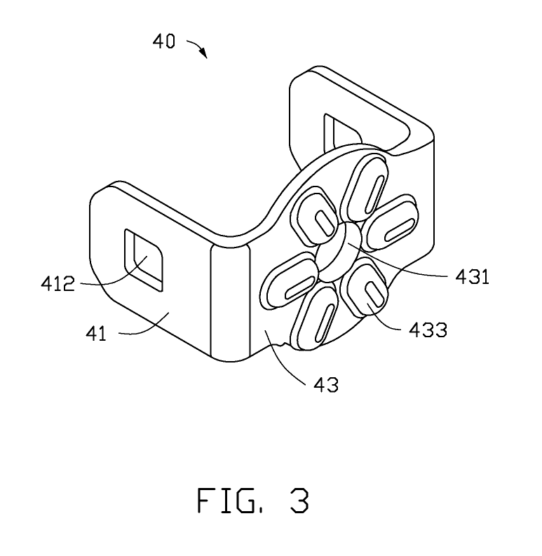

Referring to FIG. 3, each shock absorbing member 40 is made of resilient material, such as rubber. Each shock absorbing member 40 includes a resilient pad 43, and two resilient arms 41 extending from opposite ends of the resilient pad 43. A through hole 431 is defined in a middle of the resilient pad 43. A plurality of radially arranged resilient protrusions 433 is formed on an outer surface of the resilient pad 43 around the through hole 431. The resilient arms 41 are bendable and rotatable relative to the resilient pad 43. A hooking slot 412 is defined in a middle of each resilient arm 41.

Each fastener 50 includes a head 51 and a pin 53 extending from a side of the head 51.

Referring to FIG. 2, in assembly, the fasteners 50 are respectively fixed to the fixing arms 31 of the frame 30. The pins 53 of the fasteners 50 are respectively extended through the recesses 313 and the corresponding through holes 312, and are exposed out of inner surfaces of the corresponding fixing arms 31. The heads 51 are respectively received in the recesses 313. In the embodiment, the fasteners 50 are respectively fixed to the fixing arms 31 by hot melt. In other embodiments, the fasteners 50 are respectively fixed to the fixing arms 31 by screws or hooks. Then the shock absorbing members 40 are placed at inner sides of the fixing arms 31, and the through holes 431 are respectively aligned with the fasteners 50. The pins 53 of the fasteners 50 are respectively extended through the through holes 431 of the resilient pads 43, and the resilient arms 41 of the shock absorbing members 40 are extended through the corresponding through slots 315 and bent toward the corresponding hooks 314, to allow the hooks 314 to engage in the corresponding hooking slots 412 of the resilient arms 41. Thereby, the shock absorbing members 40 are respectively fixed to the fixing arms 31. Inner surfaces of the resilient pads 43 cling to inner surfaces of the corresponding fixing arms 31.

The fixing arms 31 are deformed away from each other, to allow the hard disk drive 20 to be placed on the bottom wall 33, and the fixing holes 213 of the hard disk drive 20 to be respectively aligned with the pins 53 of the fasters 50. The fixing arms 31 are restored, to allow the pins 53 to be inserted into the corresponding fixing holes 213. Thereby, the hard disk drive 20 is fixed to the frame 30. Opposite ends of the hard disk drive 20 respectively engage with the connecting arm 32 and the stop plates 317. The sidewalls 21 of the hard disk drive 20 respectively abut against the protrusions 433 of the resilient pads 43, which can absorb shock and protect the hard disk drive 20 from being broken when suffers vibrations.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A fixing apparatus for fixing a hard disk drive, the hard disk drive comprising two opposite sidewalls each defining a fixing hole, the fixing apparatus comprising:
a frame comprising two opposite fixing arms to sandwich the hard disk drive;
two shock absorbing members respectively fixed to the fixing arms, each of the shock absorbing members comprising a resilient pad clinging to an inner surface of a corresponding one of the fixing arms to absorb shock between the hard disk drive and the fixing arm, and two resilient arms respectively extending from opposite ends of the resilient pad, wherein the resilient arms of each of the shock absorbing members are extended through the corresponding fixing arm and fixed to an outer surface of the corresponding fixing arm; and
two fasteners respectively fixed to the fixing arms, each of the fasteners comprising a pin extended through a corresponding one of the resilient pads to engage in a corresponding one of the fixing holes of the hard disk drive.

2. The fixing apparatus of claim 1, wherein each of the shock absorbing members is made of rubber.

3. The fixing apparatus of claim 2, wherein a through hole is defined in a middle of each resilient pad, the pin of corresponding fastener is extended through the through hole of the resilient pad.

4. The fixing apparatus of claim 3, wherein two through slots are defined in each fixing arm at opposite sides of the corresponding fastener, the resilient arms of each shock absorbing member are extended through the through slots of the corresponding fixing arm and bent to be fixed to the outer surface of the corresponding fixing arm.

5. The fixing apparatus of claim 4, wherein a hooking slot is defined in each resilient arm, two hooks are formed on the outer surface of each fixing arm, to engage in the hooking slots of the corresponding resilient arms.

6. The fixing apparatus of claim 1, wherein a through hole is defined in each fixing arm, a recess is defined in the outer surface of each fixing arm in communication with the corresponding through hole of the fixing arm, each fastener further comprises a head received in the corresponding recess, the pins of the fasteners respectively extend through the recesses, the corresponding through holes, and the corresponding resilient pads, and extend into the frame to engage in the corresponding fixing holes of the hard disk drive.

7. The fixing apparatus of claim 6, wherein the fasteners are respectively fixed to the fixing arms by hot melt.

8. The fixing apparatus of claim 1, wherein the fixing arms are resilient, the frame further comprises a connecting arm connected between first ends of the fixing arms, and a bottom wall connected between bottoms of the fixing arms.

9. The fixing apparatus of claim 8, wherein two stop plates extend toward each other from second ends of the fixing arms away from the connecting arm.

10. The fixing apparatus of claim 1, wherein a plurality of resilient protrusions is formed on a side of each resilient pad to abut against a corresponding one of the sidewalls of the hard disk drive.
